(19) United States
(12) Patent Application Publication
(10) Pub. No.: US 2014/0021640 A1
(43) Pub. Date: Jan. 23, 2014

(54) METHOD FOR ELECTRICALLY CONNECTING VERTICALLY POSITIONED SUBSTRATES

(71) Applicant: ABB Technology AG, Zurich (CH)

(72) Inventors: Gontran PÂQUES, Niederlenz (CH); Dominik Trüssel, Bremgarten (CH); Waldemar Groot, Lenzburg (CH); Stefan Ellenbroek, Kloten (CH); David Hajas, Rupperswil (CH)

(21) Appl. No.: 13/937,546

(22) Filed: Jul. 9, 2013

(30) Foreign Application Priority Data
Jul. 20, 2012 (EP) 12177216.4

(51) Int. Cl. H01L 23/00

(52) U.S. Cl. CPC H01L 24/83; H01L 24/32
USPC 257/778; 438/108

(57) ABSTRACT

A method and arrangement are disclosed for electrically connecting a contact of a first substrate to a contact of a second substrate, whereby the first substrate is positioned relative the second substrate. The method includes providing the first substrate with its contact facing towards the second substrate, providing the second substrate with its contact facing away from the first substrate, bonding a bonding medium to the contact of the first substrate, bonding the bonding medium to the first substrate thereby forming a loop, electrically connecting the contact of the second substrate to the bonding medium, and providing the second substrate with the contact on a nose or tongue extending from an edge of the second substrate. The first substrate can be positioned below the second substrate, with a contact of the first substrate connected to a contact of the second substrate.

### RELATED APPLICATION(S)

This application claims priority under 35 U.S.C. §119 to European Patent Application No. 12177216.4 filed in Europe on Jul. 20, 2012, the entire content of which is hereby incorporated by reference in its entirety.

### FIELD

The present disclosure relates to the area of electrically connecting a contact of a first substrate to a contact of a second substrate, whereby the first substrate is positioned relative (e.g., below) the second substrate.

### BACKGROUND INFORMATION

Arrangements of two substrates in a vertical direction can be, for example, used in power semiconductor modules. Power semiconductor modules can be used in high power applications to switch high voltages and currents and can include multiple power semiconductors. Because each single semiconductor has a maximum voltage and current, the power semiconductors can be combined in parallel and/or in series within the power semiconductor modules to enable use in high power applications. To facilitate manufacturing of such modules they can include multiple first substrates on which the power semiconductors are mounted. These substrates are provided with contacts for emitter, collector and base, so that the first substrates can easily be connected within the power semiconductor modules.

The first substrates can be mounted on a common base plate, which can be part of a housing of the power semiconductor module or which can be held within a housing of the power semiconductor module. In known power semiconductor modules, for example, four or six first substrates can be combined, each provided with four to six power semiconductors including power transistors, for example, insulated gate bipolar transistors (IGBT) or reverse conducting insulated gate bipolar transistors (RC-IGBT), power diodes, or other power semiconductors suitable for high power applications. For example, a first substrate can include four IGBTs and two power diodes. The first substrates are electrically connected to terminals, which provide a connection of the metallizations within the power semiconductor module. For example, the electric terminals can be connected to electric contacts of the power semiconductor module.

The power semiconductor module can include a second substrate, which provides an auxiliary connection for electrically connecting terminals corresponding to auxiliary metallizations to the electric contacts of the power semiconductor module. Accordingly, a power semiconductor module can include an arrangement of a first and a second substrate, which are positioned above each other. To provide an electric connection from the first substrate to the second substrate, in known power semiconductors modules, a connection element can be provided. The connection element, for example, an auxiliary pin, is first soldered to the respective terminal of the first substrate, and then the second substrate is soldered onto the connection element. In case multiple first substrates are connected to one second substrate, the second substrate can be soldered to auxiliary pins of the first substrates. This method for connecting the two substrates can be complicated and time consuming. Furthermore, because the power semiconductor modules underlie thermo-mechanical stress, a reliable electric connection between the two substrates is desirable.

JP 2215137A discloses in FIG. 1 and FIG. 2, a known method for electrically connecting a contact of a first substrate to a contact of a second substrate. Moreover, in WO 2011/087485 A2, an arrangement of a first and a second substrate is disclosed, whereby the first substrate is positioned below the second substrate and a contact of the first substrate is connected to a contact of the second substrate. Additionally, U.S. Patent Application Publication No. 2007/0102796 A1 shows a power semiconductor module including a substrate with auxiliary connections and connection thereto by a bond wire.

### SUMMARY

A method is disclosed for electrically connecting a contact of a first substrate to a contact of a second substrate, whereby the first substrate is positioned relative the second substrate, the method comprising: providing the first substrate with a contact facing towards the second substrate; providing the second substrate with a contact facing away from the first substrate; bonding a bonding medium to the contact of the first substrate; bonding the bonding medium to the first substrate thereby forming a loop; electrically connecting the contact of the second substrate to the bonding medium; and providing the second substrate with a nose extending from an edge of the second substrate, whereby the contact of the second substrate is provided on the nose.

A method is disclosed for electrically connecting a contact of a first substrate to a contact of a second substrate, whereby the first substrate is positioned relative to the second substrate, the method comprising: providing the first substrate with a contact facing towards the second substrate; providing the second substrate with a contact facing away from the first substrate; bonding a bonding medium to the contact of the first substrate; bonding the bonding medium to the first substrate thereby forming a loop; electrically connecting the contact of the second substrate to the bonding medium; and providing the second substrate with a tongue extending from an edge of the second substrate, whereby the contact of the second substrate is provided on the tongue.

An arrangement is disclosed comprising: a first and a second substrate, the first substrate being positioned relative to the second substrate, and a contact of the first substrate being connected to a contact of the second substrate, wherein the first substrate with its contact faces towards the second substrate, and the second substrate with its contact faces away from the first substrate; a bonding medium bonded to the contact of the first substrate thereby forming a loop, the contact of the second substrate being electrically connected to the bonding medium; and a nose extending from an edge of the second substrate, whereby the contact of the second substrate is provided on the nose.

An arrangement is disclosed comprising: a first and a second substrate, the first substrate being positioned relative the second substrate, and a contact of the first substrate being connected to a contact of the second substrate, wherein the first substrate with its contact faces towards the second substrate, and the second substrate with its contact faces away from the first substrate; a bonding medium bonded to the contact of the first substrate thereby forming a loop, the contact of the second substrate being electrically connected to the bonding medium; and a tongue extending from an edge of the second substrate, whereby the contact of the second substrate is provided on the tongue.

### BRIEF DESCRIPTION OF THE DRAWINGS

These and other aspects of the disclosure will be apparent from and elucidated with reference to the exemplary embodiments described hereinafter.

In the drawings:

FIG. 1 shows an arrangement of two substrates with contacts connected by a bonding wire according to a first exemplary embodiment of the disclosure; and

FIG. 2 shows an arrangement of two substrates with contacts connected by a bonding wire according to a second exemplary embodiment of the disclosure.

### DETAILED DESCRIPTION

The present disclosure provides exemplary methods for electrically connecting a contact of a first substrate to a contact of a second substrate, which allow easily and rapidly providing a reliable electric connection between contacts of the first and second substrates with an increased resistance to mechanical and thermal influences. Exemplary embodiments of the present disclosure provide an arrangement of a first and a second substrate and a power semiconductor module including such an arrangement, which are easy to manufacture and which are provided with a reliable electric connection between contacts of the first and second substrates with an increased resistance to mechanical and thermal influences.

Exemplary embodiments of the present disclosure provide a method for electrically connecting a contact of a first substrate to a contact of a second substrate, whereby the first substrate is positioned relative (e.g., below) the second substrate, including providing the first substrate with its contact facing towards the second substrate, providing the second substrate with its contact facing away from the first substrate, bonding a bonding medium to the contact of the first substrate, bonding the bonding medium to the first substrate thereby forming a loop, and electrically connecting the contact of the second substrate to the bonding medium.

Exemplary embodiments of the present disclosure provide an arrangement of a first and a second substrate, whereby the first substrate is positioned (e.g., below) the second substrate, wherein a contact of the first substrate is connected to a contact of the second substrate according to the above method.

Exemplary embodiments of the present disclosure also provide a power semiconductor module including such an arrangement.

Exemplary embodiments of the disclosure use a bonding medium for connecting the contacts of the two substrates. The bonding medium, which can be a bonding wire or a bonding ribbon, passes on top of the second substrate and can be easily connected to the substrates in a known way, so that the manufacturing process can be easily performed. The connection of the bonding medium can be made to the contacts of both substrates can be made from the same direction, which facilitates the production of the arrangement of the two substrates and the power semiconductor module. With the loop formed in the bonding medium, the connection of the two substrates is flexible, so that a relative movement of the two substrates is enabled. Accordingly, thermo-mechanical stress resistance of the arrangement of the two substrates and the power semiconductor module can be improved. Also shocks and vibrations can be decoupled between the two substrates. Further, the bonding medium is cut after bonding to the first substrate. Accordingly, the length of the bonding medium on the first substrate can be adapted during the bonding process. Bonding can be easily performed by use of common bonding equipment. The step of bonding the bonding medium to the first substrate thereby forming a loop can include bonding the bonding medium to any suitable place on the first substrate. For example, an isolated metallization, such as an island, can be provided on the first substrate merely for the purpose of connection of the bonding medium to enable the loop configuration thereof. Bonding can be performed using any known bonding technique.

Although the method steps are listed in a particular order, this does not imply any order in which the method steps have to be performed. The steps can be performed in different orders, as further detailed below. For example, the steps of bonding a bonding medium to the contact of the first substrate and bonding the bonding medium to the first substrate thereby forming a loop can be substituted, so that the loop can be formed when the bonding medium is bonded to the contact of the first substrate.

According to an exemplary embodiment of the disclosure, the steps of bonding a bonding medium to the contact of the first substrate and bonding the bonding medium to the first substrate thereby forming a loop are executed prior to the step of connecting the contact of the second substrate to the bonding medium, and the method can include prior to the step of connecting the contact of the second substrate to the bonding medium the additional step of inserting the second substrate through the loop. In other words, the bonding medium is first bonded to the first substrate, so that the loop is formed and connected thereto, and then the second substrate is at least partially inserted into the loop so that the loop passes over the contact of the second substrate for electrically connecting it thereto in a subsequent step. Accordingly, the bonding medium can be guided above the second substrate to the contact of the second substrate. With the loop formed prior to the connection of the bonding medium to the contact of the second substrate, bonding of the bonding medium can be easily performed. Still, it does not matter which end of the loop is bonded first to the first substrate.

According to an exemplary embodiment of the disclosure, the step of electrically connecting the contact of the second substrate to the bonding medium is performed prior to the step of bonding the bonding medium to the first substrate thereby forming a loop, and the step of electrically connecting the contact of the second substrate to the bonding medium includes bonding the bonding medium to the contact of the second substrate. In other words, a continuous bonding process is performed for electrically connecting the contacts of the two substrates. First, the bonding medium is bonded to the first substrate, then the bonding medium is bonded to the contact of the second substrate, and the loop is completed by bonding the bonding medium to the first substrate. Preferably, the bonding medium is additionally fixed to the contact of the second substrate after being bonded thereto to increase the strength of the connection. Still, it does not matter which end of the loop is bonded first to the first substrate.

An exemplary embodiment can include providing the second substrate with a nose extending from an edge of the second substrate, whereby the contact of the second substrate is provided on the nose. The nose of the second substrate facilitates the placement of the bonding medium and its connection to the substrates. The nose can be easily inserted into the loop. Furthermore, the nose allows simple access to the first substrate for bonding the bonding medium thereto, when the first substrate is already positioned below the second substrate. The nose can be located in the plane of the second substrate.

An exemplary embodiment can include providing the second substrate with two notches forming a tongue there between, whereby the contact of the second substrate is provided on the tongue. The tongue of the second substrate facilitates the placement of the bonding medium and its connection to the substrates. The tongue can be easily inserted into the loop by inserting the bonding medium into the notches. The bonding medium can be positioned in the notches so that is it supported in its position during the connection process. The tongue can be located in the plane of the second substrate. Further, the tongue is provided within the circumference of the second substrate.

A modified exemplary embodiment can include providing the nose or the tongue with a smaller extension at its end connected to the second substrate compared to the extension of its free end, and the step of inserting the second substrate through the loop includes passing the bonding medium over the end of the nose or tongue with the greater extension. When the bonding medium is passed over the end with the greater extension, it is automatically secured on the nose or tongue, which further facilitates the manufacturing process. Unintended movements of the two substrates relative to each other during the manufacturing process do not automatically require a repeated positioning of the bonding medium over the contact of the second substrate.

According to an exemplary embodiment of the disclosure, the step of providing the nose or the tongue with a smaller extension at its end connected to the second substrate compared to the extension of its free end includes providing the nose or the tongue with a T-shape or an anchor-shape. These shapes can be easily formed and allow simple insertion of the nose or tongue into the loop, whereas unintended removal of the nose or tongue through the loop is avoided due to the chosen shape.

According to an exemplary embodiment of the disclosure, the step of electrically connecting the contact of the second substrate to the bonding medium can include, for example, gluing, bonding, welding, soldering or brazing. These steps can be performed to provide a mechanical and electrical connection between the bonding medium and the contact of the second substrate. Also, different connection steps can be combined. In particular, the bonding medium can first be bonded to the contact, and then the connection can be strengthened by applying an additional connection step, for example, soldering or welding. The same connection techniques can be applied to the connection of the bonding medium to the first substrate in addition the bonding steps.

According to an exemplary embodiment of the disclosure, the step of bonding the bonding medium to the first substrate thereby forming a loop includes bonding the bonding medium to the contact of the first substrate. In other words, the bonding medium is bonded twice to the same contact of the first substrate, so that a redundant electric path is established between the contacts of the two substrates. In case of failure of one path, for example, the bonding medium is cut for any reason, the remaining path can provide the electrical connection between the two contacts. Preferably, the contact of the first substrate has a size bigger than the contact of the second substrate, so that the loop can be easily formed.

An exemplary embodiment of the disclosure includes the step of providing the bonding medium made of copper. Copper is a suitable material for bonding because it can generally be bonded to different materials. Nevertheless, also other materials, for example, aluminum, can be used for the bonding medium.

An exemplary embodiment of the disclosure includes the step of providing the contacts of the first and second substrate and the bonding medium made of the same material. The connection between the contacts and the bonding medium can be easily formed and have a high robustness when the same material is used. Further, also the island on the first substrate, if present, is made of the same material.

An exemplary embodiment of the disclosure includes the step of providing a as bonding medium a thin bonding wire having a diameter of 400 μm or less. The thin bonding wire facilitates forming the loop in the bonding process.

According to an exemplary embodiment of the disclosure, contacts of multiple first substrates are connected to contacts of one second substrate.

According to an exemplary embodiment of the disclosure, power semiconductors are mounted on the first substrate and the second substrate is provided as an auxiliary connection for providing an auxiliary contact of the power semiconductor module.

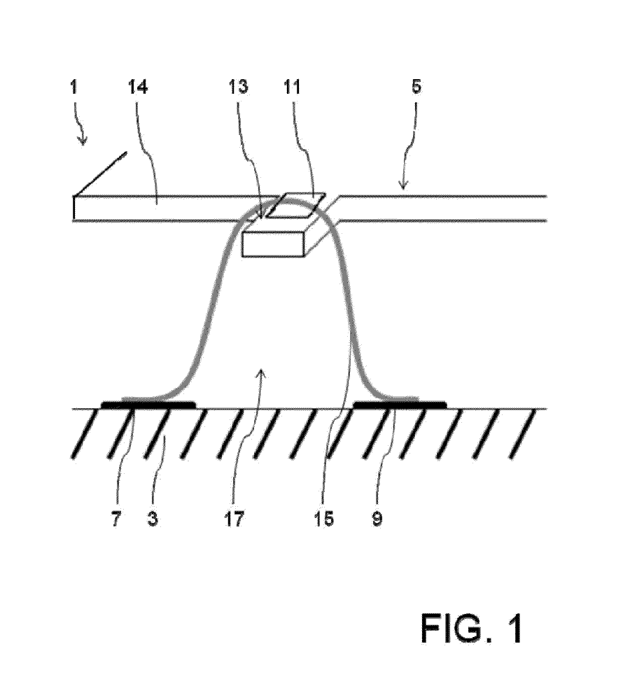

FIG. 1 shows an arrangement 1 of a first and a second substrate 3, 5 according to a first exemplary embodiment. The first substrate 3 is positioned relative (e.g., below) the second substrate 5, and the arrangement 1 is made for use in a power semiconductor module. Accordingly, power semiconductors are mounted on the first substrate 3 and the second substrate 5 is provided as an auxiliary connection for providing an auxiliary contact of the power semiconductor module.

The first substrate 3 has a two metallizations 7, 9, from which one metallization 7 refers to a contact 7 of the first substrate 3. The second metallization 9 is provided as an island on the first substrate 3 without electrical function.

As can be seen in FIG. 1, the second substrate 5 has one contact 11, which is positioned on a nose 13 extending from an edge 14 of the second substrate 5. Accordingly, the contact 7 of the first substrate 3 faces towards the second substrate 5, and the contact 11 of the second substrate 5 faces away from the first substrate 3.

The contact 7 of the first substrate 3, the island 9, and the contact 11 of the second substrate 5 are connected by bonding medium 15, which is a bonding wire 15 in this exemplary embodiment. The bonding wire 15 in this exemplary embodiment has a diameter of 375 μm. The contacts 7, 11 of the first and second substrate 3, 5, the island 9, and the bonding wire 15 are made of the same material, which can be copper in this exemplary embodiment.

A method for electrically connecting the contacts 7, 11 of the two substrates 3, 5 according to the first exemplary embodiment will now be described.

Initially, the first substrate 3 and the second substrate 5 are provided, whereby the contact 7 and the island 9 of the first substrate 3 face towards the second substrate 5 and the contact 11 of the second substrate 5 faces away from the first substrate 3.

Subsequently, the bonding wire 15 is bonded to the contact 7 of the first substrate 3. Next, the bonding wire 15 is electrically connected to the contact 11 of the second substrate 5 by bonding. In a subsequent step, a loop 17 is formed in the bonding wire 15 by bonding the bonding wire 15 to the island 9 of the first substrate 3. After bonding the bonding wire 15 to the island 9 of the first substrate 3, the bonding wire 15 is cut off so that a bonding tool used for bonding the bonding wire 15 can be used bonding further bonding wires 15.

The connection of the contact 11 of the second substrate 5 to the bonding wire 15 is then reinforced by an additional soldering step applied to this connection.

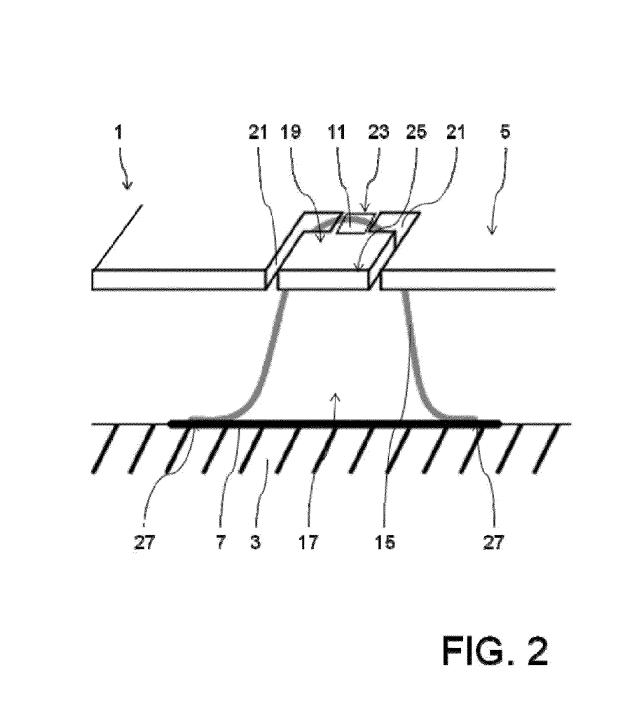

FIG. 2 shows an arrangement 1 of a first and a second substrate 3, 5 according to a second exemplary embodiment. The arrangement 1 of the second exemplary embodiment is similar to the arrangement 1 of the first exemplary embodiment, so that it is described using the same reference numerals for similar components.

The first substrate 3 is positioned below the second substrate 5, and the arrangement 1 is made for use in a power semiconductor module. Accordingly, power semiconductors are mounted on the first substrate 3 and the second substrate 5 is provided as an auxiliary connection for providing an auxiliary contact of the power semiconductor module.

The first substrate 3 has one metallization 7, which refers to a contact 7 of the first substrate 3. As can be seen in FIG. 1, the second substrate 5 has one contact 11, which is positioned on a tongue 19 of the second substrate 5. The tongue 19 is formed between two notches 21 within a circumference of the second substrate 5. The tongue 19 is provided with a T-shape, so that it has a smaller extension at its end 23 connected to the second substrate 5 compared to the extension of its free end 25.

As can be seen in FIG. 2, the contact 7 of the first substrate 3 faces towards the second substrate 5, and the contact 11 of the second substrate 5 faces away from the first substrate 3.

A bonding medium 15, which is a bonding wire 15 in this exemplary embodiment, is connected at its ends 27 to the contact 7 of the first substrate 3, thereby forming a loop 17. Additionally, the bonding wire 15 is connected to the contact 11 of the second substrate 5. The bonding wire 15 in this exemplary embodiment has a diameter of 375 μm. The contacts 7, 11 of the first and second substrate 3, 5 and the bonding wire 15 are made of the same material, which is copper in this exemplary embodiment.

A method for electrically connecting the contacts 7, 11 of the two substrates 3, 5 according to the second exemplary embodiment will now be described.

Initially, the first substrate 3 and the second substrate 5 are provided, whereby the contact 7 of the first substrate 3 faces towards the second substrate 5 and the contact 11 of the second substrate 5 faces away from the first substrate 3.

Subsequently, the bonding wire 15 is bonded to the contact 7 of the first substrate 3 and the loop 17 is formed in the bonding wire 15 by bonding the bonding wire 15 again to the contact 7 of the first substrate 3. Subsequently, the bonding wire 15 is cut off so that a bonding tool can be used bonding further bonding wires 15.

In a following step, the tongue 19 of the second substrate 5 is inserting through the loop 17 so that the bonding wire 15 is guided above the contact 11 of the second substrate 5. Accordingly, the bonding wire 15 is passed over the free end 25 of the tongue 19 and the bonding wire 15 is positioned above the contact 11, which is located in a different area of the tongue 19 at its end 23 connected to the second substrate 5.

Next, the bonding wire 15 is electrically connected to the contact 11 of the second substrate 5 by means of soldering or a different connection step.

Thus, it will be appreciated by those skilled in the art that the present invention can be embodied in other specific forms without departing from the spirit or essential characteristics thereof. The presently disclosed exemplary embodiments are therefore considered in all respects to be illustrative and not restricted. The scope of the invention is indicated by the appended claims rather than the foregoing description and all changes that come within the meaning and range and equivalence thereof are intended to be embraced therein.

### REFERENCE SIGNS LIST

1 arrangement
3 first substrate
5 second substrate
7 first metallization, contact of first substrate
9 second metallization, island
11 contact of second substrate
13 nose
14 edge of second substrate
15 bonding medium, bonding wire
17 loop
19 tongue
21 notch
23 end of tongue connected to the second substrate
25 free end of tongue
27 end of bonding wire

What is claimed is:

1. A method for electrically connecting a contact of a first substrate to a contact of a second substrate, whereby the first substrate is positioned relative the second substrate, the method comprising:
providing the first substrate with a contact facing towards the second substrate;
providing the second substrate with a contact facing away from the first substrate;
bonding a bonding medium to the contact of the first substrate;
bonding the bonding medium to the first substrate thereby forming a loop;
electrically connecting the contact of the second substrate to the bonding medium; and
providing the second substrate with a nose extending from an edge of the second substrate, whereby the contact of the second substrate is provided on the nose.

2. The method according to claim 1, wherein the bonding of a bonding medium to the contact of the first substrate and bonding the bonding medium to the first substrate thereby forming a loop are executed prior to connecting the contact of the second substrate to the bonding medium; and the method comprises:
prior to connecting the contact of the second substrate to the bonding medium, inserting the second substrate through the loop.

3. The method according to claim 1, wherein the electrically connecting of the contact of the second substrate to the bonding medium is performed prior to bonding the bonding medium to the first substrate thereby forming a loop; and the electrically connecting of the contact of the second substrate to the bonding medium comprises:
bonding the bonding medium to the contact of the second substrate.

4. The method according to claim 2, comprising:
providing the nose with a smaller extension at an end connected to the second substrate compared to an extension of another free end; and
inserting the second substrate through the loop by passing the bonding medium over the free end of the nose with a greater extension. and positioning the bonding medium in a different area of the nose.

5. The method according to claim 4, wherein the providing of the nose with a smaller extension at the end connected to the second substrate compared to the extension of the free end comprises:
providing the nose with a T-shape or an anchor-shape.

6. The method according to claim 1, wherein the electrically connecting of the contact of the second substrate to the bonding medium comprises:
gluing, bonding, welding, soldering or brazing the contact of the second substrate to the bonding medium.

7. The method according to claim 1, wherein the bonding of the bonding medium to the first substrate to form a loop comprises:
bonding the bonding medium to the contact of the first substrate.

8. The method according to claim 1,
wherein the bonding medium is made of copper.

9. The method according to claim 1,
wherein the contacts of the first and second substrate and the bonding medium made of a same material.

10. A method for electrically connecting a contact of a first substrate to a contact of a second substrate, whereby the first substrate is positioned relative to the second substrate, the method comprising:
providing the first substrate with a contact facing towards the second substrate;
providing the second substrate with a contact facing away from the first substrate;
bonding a bonding medium to the contact of the first substrate;
bonding the bonding medium to the first substrate thereby forming a loop;
electrically connecting the contact of the second substrate to the bonding medium; and
providing the second substrate with a tongue extending from an edge of the second substrate, whereby the contact of the second substrate is provided on the tongue.

11. The method according to claim 10, wherein the bonding of a bonding medium to the contact of the first substrate and bonding the bonding medium to the first substrate thereby forming a loop are executed prior to connecting the contact of the second substrate to the bonding medium; and the method comprises:
prior to connecting the contact of the second substrate to the bonding medium inserting the second substrate through the loop.

12. The method according to claim 10, wherein the electrically connecting of the contact of the second substrate to the bonding medium is performed prior to the bonding of the bonding medium to the first substrate thereby forming a loop; and the electrically connecting of the contact of the second substrate to the bonding medium comprises:
bonding the bonding medium to the contact of the second substrate.

13. The method according to claim 10, wherein the electrically connecting of the contact of the second substrate to the bonding medium comprises:
gluing, bonding, welding, soldering or brazing the contact of the second substrate to the bonding medium.

14. The method according to claim 10, wherein the bonding of the bonding medium to the first substrate thereby forming a loop comprises:
bonding the bonding medium to the contact of the first substrate.

15. The method according to claim 10, comprising:
providing the tongue with a smaller extension at an end connected to the second substrate compared to the extension of another free end; and
inserting the second substrate through the loop by passing the bonding medium over the free end of the tongue with a greater extension, and positioning the bonding medium in a different area of the tongue.

16. The method according to claim 15, wherein the providing of the tongue with a smaller extension at the end connected to the second substrate compared to the extension of the free end comprises:
providing the tongue with a T-shape or an anchor-shape.

17. An arrangement comprising:
a first and a second substrate, the first substrate being positioned relative to the second substrate, and a contact of the first substrate being connected to a contact of the second substrate, wherein the first substrate with its contact faces towards the second substrate, and the second substrate with its contact faces away from the first substrate;
a bonding medium bonded to the contact of the first substrate thereby forming a loop, the contact of the second substrate being electrically connected to the bonding medium; and
a nose extending from an edge of the second substrate, whereby the contact of the second substrate is provided on the nose.

18. The arrangement according to claim 17, wherein
contacts of a plurality of first substrates are connected to contacts of one second substrate.

19. The arrangement according to claim 17, comprising:
a power semiconductor module.

20. The arrangement according to claim 19, comprising:
power semiconductors mounted on the first substrate, the second substrate being an auxiliary connection for providing an auxiliary contact of the power semiconductor module.

21. An arrangement comprising:
a first and a second substrate, the first substrate being positioned relative the second substrate, and a contact of the first substrate being connected to a contact of the second substrate, wherein the first substrate with its contact faces towards the second substrate, and the second substrate with its contact faces away from the first substrate;
a bonding medium bonded to the contact of the first substrate thereby forming a loop, the contact of the second substrate being electrically connected to the bonding medium; and
a tongue extending from an edge of the second substrate, whereby the contact of the second substrate is provided on the tongue.

22. The arrangement according to claim 21, wherein contacts of a plurality of first substrates are connected to contacts of one second substrate.

23. The arrangement according to claim 21, comprising:
power semiconductor module.

24. The arrangement according to claim 21, comprising:
power semiconductors mounted on the first substrate, the second substrate being an auxiliary connection for providing an auxiliary contact of the power semiconductor module.
